(19) United States
(12) Patent Application Publication
(10) Pub. No.: US 2003/0155625 A1
(43) Pub. Date: Aug. 21, 2003

(54) Semiconductor light receiving device and semiconductor part

(76) Inventors: Masanobu Kato, Hokkaido (JP); Takashi Ueda, Tokyo (JP); Ryozo Furukawa, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/298,904

(22) Filed: Nov. 19, 2002

(30) Foreign Application Priority Data
Feb. 19, 2002 (JP) 041749/2002

(51) Int. Cl. H01L 33/00; H01L 31/0232

(52) U.S. Cl. 257/432; 257/98

(57) ABSTRACT

Disclosed is a semiconductor light receiving device which receives only long-wavelength side light, annihilates carriers generated in an optical filter layer without application of a voltage and prevents generation of noise. The semiconductor light receiving device includes a semiconductor substrate, an optical filter layer formed on the semiconductor substrate, a first conductivity type contact layer formed on the optical filter layer, a light receiving layer formed on the first conductivity type contact layer, a second conductivity type contact layer formed on the light receiving layer, a first conductivity type electrode formed on the first conductivity type contact layer, a second conductivity type electrode formed on the second conductivity type contact layer, and an antireflection film formed on a back surface of the semiconductor substrate. The optical filter layer annihilates carriers generated therein by radiative recombination and decreases the intensity of short-wavelength side light produced by the radiative recombination.

### BACKGROUND OF THE INVENTION

1. Field of the Invention

The present invention relates to a semiconductor light receiving device for optical communication in 1-μm band, and, more particularly, to a semiconductor light receiving device capable of selectively receiving long-wavelength side light in two-wavelength multiplex communication, and a semiconductor part capable of selectively passing long-wavelength side light.

2. Description of the Related Art

Lights having wavelengths of 1.3 μm, 1.55 μm and so forth are used in optical communication in 1-μm ban, particularly, for light for a surface-mounted optical module. A light receiving device which selectively receives only 1.55-μm side light has conventionally taken such a structure as to include a light receiving layer (e.g., indium gallium arsenic: InGaAs) and an optical filter layer (e.g., indium gallium arsenic phosphorus: InGaAsP) whose bandgap wavelength is shorter than that of the light receiving layer whereby the optical filter layer absorbs only short-wavelength (e.g., 1.3 μm) side light so that only long-wavelength (e.g., 1.55 μm) side light is selectively received, as disclosed in Japanese Document 10-245116 entitle “Semiconductor Light Receiving Device” by Ryozo Furukawa and Masanobu Katou.

However, the combination of the InGaAs light receiving layer and the InGaAsP optical filter layer whose bandgap wavelength is shorter than that of the light, receiving layer allows the optical filter layer to absorb short-wavelength side light (primary light), generating carriers. In case where no voltage is applied to this optical filter layer, the carriers stay and light (secondary light) of a wavelength nearly equal to the bandgap wavelength of the InGaAsP optical filter layer is emitted due to radiative recombination. Because this light is received by the InGaAs light receiving layer, the short-wavelength side light behaves as if it was received by the InGaAs light receiving layer. This makes it possible to selectively receive long-wavelength side light, thus dropping the selectivity ratio of long-wavelength side light.

As a solution to this shortcoming, there are two methods conceived: the first method is to forcibly eliminate carriers generated by short-wavelength side light (primary light) to thereby prevent radiative recombination (generation of secondary light) and the other one is to lengthen the distance between the optical filter layer and the light receiving layer to thereby reduce the probability of the secondary light entering the light receiving portion in view of the solid angle for the secondary light is emitted in all directions. The second method is described in Document 2000 General Conference C-3-131 of the Institute of Electronics, Information and Communication (EIC) Engineers “1.3/1.55 μm Transmitting/Receiving Module with Low Crosstalk and High Sensitivity Using Double-layer Filter PD” by Hiromi Nakanishi, et al.

FIG. 1 shows the cross section of the light receiving device disclosed in this document. Formed on a semiconductor substrate 10 in order are a first n-InGaAsP optical filter layer 11 whose bandgap wavelength is longer than that of short-wavelength side light and shorter than that of long-wavelength side light, an n-InP layer 12, an n-InGaAs light receiving layer 13 whose bandgap wavelength is longer than that of that of the long-wavelength side light and an n-InP layer 14, a p=InP layer 15 is selectively diffused into the topmost n-InP layer 14, and a p type electrode 16 is formed on the p-InP layer 15. A second n-InGaAsP filter layer 17 whose bandgap wavelength is longer than that of the short-wavelength side light and shorter than that of the long-wavelength side light is formed on the back surface of the semiconductor substrate 10, and an n type electrode 18 is formed on the filter layer 17. A passivation film is formed on the n-InP layer 14 and an antireflection film 19 is formed on the light input surface or the back surface of the semiconductor substrate 10.

When light containing two wavelengths is input from the back of the thus constituted light receiving device, short-wavelength (1.3 μm) side light is absorbed by the second n-InGaAsP filter layer 17 whose bandgap wavelength is shorter than that of the n-InGaAs light receiving layer 13 and long-wavelength (1.55 μm) side light is transmitted. At the same time, carriers are generated in the second n-InGaAsP filter layer 17 and secondary light is generated due to recombination. Because there is a distance between the place of the generation and the n-InGaAs light receiving layer 13, the probability that the secondary light enters the light receiving portion is reduced and is the secondary light is absorbed again by the first n-InGaAsP optical filter layer 11, thus ensuring efficient reception of long-wavelength side light.

The first method has the following problems. First, a large amount of carriers generated in the optical filter layer become noise. Secondary, while a photodiode (PD) which is an ordinary light receiving device has two electrodes, a p type and an type, at least one more electrode should be provided to forcibly eliminate the carriers. That is, a total of at least three electrodes should be provided. Further, a module design which allows a voltage to be applied to the optical filter layer of the device should be taken at the time of mounting.

The second method likewise has the following problems. First, a large amount of carriers generated in the optical filter layer become noise as in the first method. Secondary, because epitaxial growth is performed on the back side of the device, the back side cannot be polished, thus making dicing difficult. Further, if epitaxial growth is carried out after polishing the back side in order to make the device thinner, the high temperature at the time of epitaxial growth progresses the diffusion of the selective diffusion region p⁺-InP. This impairs the device characteristics.

### SUMMARY OF THE INVENTION

The invention has been devised to over the aforementioned problems of the conventional semiconductor light receiving devices and aims at providing a novel and improved semiconductor light receiving device which annihilates carriers generated in an optical filter layer not by a voltage-applying method that reduces the processability and the design efficiency, prevents the carriers from becoming noise and thus can selectively receive only long-wavelength side light without reception of secondary light on the short-wavelength side originated from recombination.

To achieve the object, according to the first aspect of the invention, there is provided a semiconductor light receiving device which receives only long-wavelength side light in input light containing two wavelengths short-wavelength side light, and comprises a semiconductor substrate, an optical filter layer formed on the semiconductor substrate; a first conductivity type contact layer formed on the optical filter layer; a light receiving layer having a bandgap wavelength longer than that of the long-wavelength side light and formed on the first conductivity type contact layer; a second conductivity type contact layer formed on the light receiving layer; a first conductivity type electrode formed on the first conductivity type contact layer; a second conductivity type electrode formed on the second conductivity type contact layer; and an antireflection film formed on a back surface of the semiconductor substrate, whereby the optical filter layer annihilates carriers, generated in the optical filter layer by absorption of short-wavelength side light, by radiative recombination and decreases an intensity of short-wavelength side light produced by the radiative recombination.

The use of the light receiving device can annihilate carriers generated in the optical filter layer by radiative recombination and can reduce the intensity of secondary light on the short-wavelength side. It is therefore possible to selectively receive only long-wavelength side light and suppress the noise level low. Because no voltage is applied to the voltage to forcibly eliminate carriers, a complicated electrode structure is not needed.

As a first example of the optical filter layer, the optical filter layer can take a multi-quantum well structure having a combination of a barrier layer having a bandgap wavelength which is an intermediate wavelength between wavelengths of the long-wavelength side light and the short-wavelength side light in the input light containing the two wavelengths and a well layer having a bandgap wavelength equal to or longer than that of the light receiving layer. It is preferable that the total thickness of the well layer should be such that an absorption loss of the long-wavelength side light is negligible.

The short-wavelength side light in the input light containing two wavelengths which is input to the first example of the optical filter layer from the back side of the device is absorbed by the barrier layer, thus generating carriers. The carriers are diffused and stay in the well layer to undergo radiative recombination. While the short-wavelength side light is also absorbed by the well layer, the secondary light which has been generated in the well layer by radiative recombination has a bandgap wavelength equal to or longer than that of the light receiving layer so that the secondary light is not received by the light receiving layer. Although the long-wavelength side light is also absorbed by the well layer then, the absorption loss is negligible for the total thickness of the well layer is small.

As a second example of the optical filter layer, the optical filter layer can take such a structure in which the optical filter layer is a lamination of a plurality of layers having bandgap wavelengths longer than that of the short-wavelength side light in the input light containing the two wavelengths and shorter than that of the light receiving layer, and the bandgap wavelengths of the plurality of layers become longer and thickness of the plurality of layers become thinner in a light traveling direction.

With the use of the second example of the optical filter layer, the short-wavelength side light in the two-wavelength containing input light which is input from the back side of the device is absorbed first by the lowermost layer of the plurality of layers, thus generating carriers. The carriers are recombined to generate secondary light. As the bandgap wavelengths of the plurality of layers becomes longer in the light traveling direction, the secondary light is absorbed by the next layer, thus generating third-order light. When the light reaches the light receiving layer as the process is repeated, the intensity of the short-wavelength side light drops low enough to exert no influence. While the absorption ratio of the long-wavelength side light, on the other hand, increases in the light traveling direction, the light loss can be suppressed due to the layers becoming thinner. As a result, only the long-wavelength side light can be received.

As a third example of the optical filter layer, the optical filter layer can take such a structure in which the optical filter layer is a lamination of a plurality of layers having bandgap wavelengths longer than that of the short-wavelength side light in the input light containing the two wavelengths and shorter than that of the light receiving layer, in pairs with the barrier layer having a bandgap wavelength shorter than the bandgap wavelengths of the plurality of layers, and the bandgap wavelengths of the plurality of layers become longer and thickness of the plurality of layers become thinner in a light traveling direction.

In the case of using the second example of the optical filter layer, carriers generated in the lowermost layer may be diffused, thus generating secondary light in the vicinity of the light receiving layer. This does not give a good influence on the effect of reducing the light intensity. In case of using the third example of the optical filter layer, by way of contrast, as diffusion of the carriers is forcibly blocked by the barrier layer which makes pairs with the layers of the optical filter layer, radiative recombination occurs in each filter layer so that the intensity of short-wavelength side light is surely weakened until the light reaches the light receiving layer and long-wavelength side light alone can be received.

As a fourth example of the optical filter layer, the optical filter layer can take such a structure in which the optical filter layer has a bandgap wavelength which is an intermediate wavelength between wavelengths of the long-wavelength side light and the short-wavelength side light in the input light containing the two wavelengths and contains an impurity to thereby form an impurity level.

When the fourth example of the optical filter layer is used, the short-wavelength side light in the input light containing two wavelengths which is input from the back side of the device is absorbed by the optical filter layer, thus generating carriers. The carriers however fall to the impurity level. Although the carriers at the impurity level are recombined to generate secondary light, the secondary light is not absorbed by the light receiving layer when the bandgap wavelength of the secondary light is equal to or longer than that of the light receiving layer. This can improve the selectivity ratio of long-wavelength side light.

According to the second aspect of the invention, there is provided a semiconductor part which receives only long-wavelength side light in input light containing two wavelengths short-wavelength side light, and comprises a semiconductor substrate, an optical filter layer formed on the semiconductor substrate; an antireflection film formed on the optical filter layer; and an antireflection film formed on a back surface of the semiconductor substrate, whereby the optical filter layer annihilates carriers, generated in the optical filter layer by absorption of short-wavelength side light, by radiative recombination and decreases an intensity of short-wavelength side light produced by the radiative recombination.

The semiconductor part uses the optical filter portion of the semiconductor light receiving device according to the first aspect of the invention as separate from the light receiving portion. When two-wavelength containing input light is input to the semiconductor part, carriers generated by absorption of short-wavelength side light are annihilated by radiative recombination, without forcible elimination by voltage application. This eliminates the need for a complicated electrode structure, can ensure selective transmission of only long-wavelength side light and can allow the semiconductor part alone to serve as a bandpass filter.

As a first example of the optical filter layer of the semiconductor part, the first to fourth examples of the optical filter layer of the semiconductor light receiving device according to the first aspect of the invention can be used with the same advantages.

As a second example of the optical filter layer, the optical filter layer can take such a structure in which the optical filter layer is a lamination of a plurality of layers having bandgap wavelengths longer than that of the short-wavelength side light in the input light containing the two wavelengths and shorter than that of the light receiving layer, in pairs with the barrier layer having a bandgap wavelength which is an intermediate wavelength between wavelengths of the long-wavelength side light and the short-wavelength side light in the input light containing the two wavelengths, and the bandgap wavelengths thickness of the plurality of layers temporarily become shorter and thicker respectively, and then become longer and thinner in a light traveling direction.

In the case of using the first example of the optical filter layer, long-wavelength side light whose wavelength cannot be absorbed by the light receiving layer are emitted from the transmission side of the filter and multiple lights whose wavelengths are equal to or longer than the bandgap wavelength of each filter layer are mixed and are emitted on the input side. In the case of using the second example of the optical filter layer, however, long-wavelength side light is emitted on both the transmission side and input side of the filter, thus facilitating matching, so that an adverse affect is not given on other optical devices which are connected to the semiconductor part by optical fibers.

### BRIEF DESCRIPTION OF THE DRAWINGS

FIG. 1 is a cross-sectional view of a semiconductor light receiving device according to prior art;

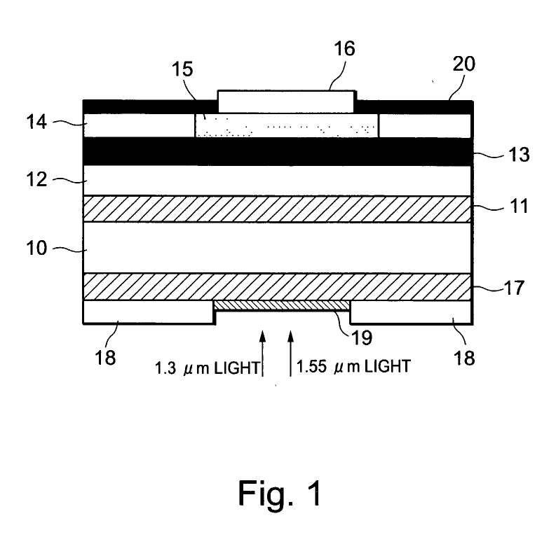

FIG. 2A is a cross-sectional view of a semiconductor light receiving device according to a first embodiment of the invention and FIG. 2B is a band structural diagram of the semiconductor light receiving device;

FIG. 3A is a cross-sectional view of a semiconductor light receiving device according to a second embodiment of the invention and FIG. 3B is a band structural diagram of the semiconductor light receiving device;

FIG. 4A is a cross-sectional view of a semiconductor light receiving device according to a third embodiment of the invention and FIG. 4B is a band structural diagram of the semiconductor light receiving device;

FIG. 5A is a cross-sectional view of a semiconductor light receiving device according to a fourth embodiment of the invention and FIG. 5B is a band structural diagram of the semiconductor light receiving device;

FIG. 6 is a schematic cross-sectional view of a semiconductor part according to a fifth embodiment of the invention; and

FIG. 7A is a cross-sectional view of a semiconductor part according to a sixth embodiment of the invention and FIG. 7B is a band structural diagram of the semiconductor part.

### DETAILED DESCRIPTION OF THE PREFERRED EMBODIMENTS

Preferred embodiments of a method of fabricating a semiconductor device according to the invention will now be described in detail with reference to the accompanying drawings. To avoid the redundant description, throughout the following specification and the accompanying drawings, like or same reference symbols are given to those constituting elements which substantially have the same functional structures.

(First Embodiment)

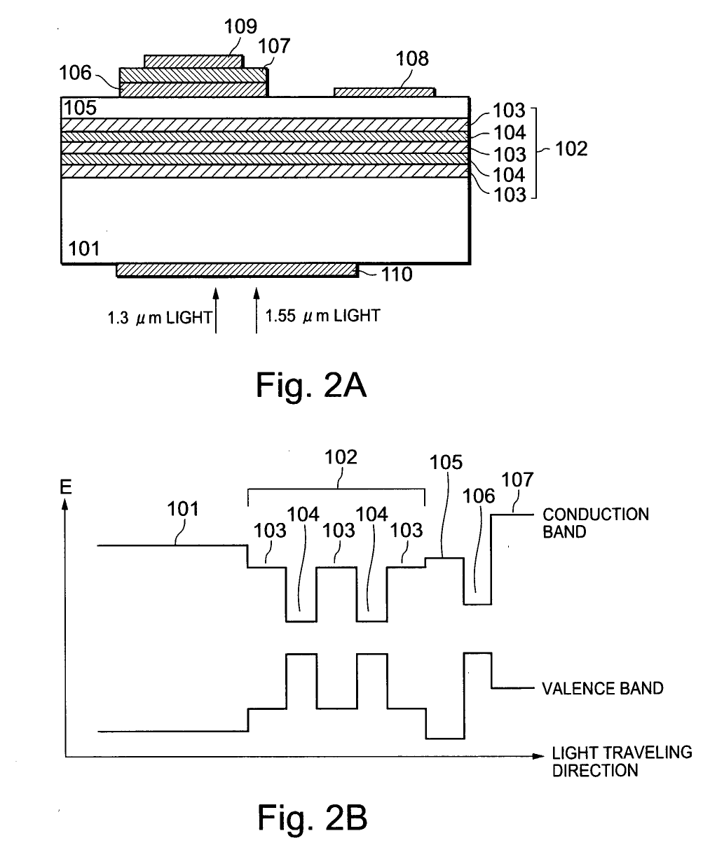

FIG. 2A presents a cross-sectional view of a light receiving device according to the first embodiment of the invention and FIG. 2B presents a band diagram of the light receiving device. According to the embodiment, it is assumed that two-wavelength containing input light is input from the back side of the device and long-wavelength (1.55 μm) side light alone is selectively received. A semiconductor substrate of InP, GaAs, Si or the like is used for a semiconductor substrate 101. An optical filter layer 102 is formed on the semiconductor substrate 101. The optical filter layer 102 takes a multi-quantum well (MQW) structure formed by a combination of a barrier layer 103 (thickness of 1 to 2 μm) and a well layer 104 (thickness of less than 1 μm).

A material that has a bandgap wavelength λg of about 1.4 μm, which is an intermediate wavelength between wavelengths of short-wavelength (1.3 μm) side light and long-wavelength (1.55 μm) side light, is used for the barrier layer 103. For example, InGaAsP, InGaAs, InAsP, GaAsSb, AlInSb, AlGaSb, AlGaAsSb, AlGaAs, InAlAs and so forth are suitable as that material. The desired bandgap wavelength is obtained by optimizing the composition ratio or the like. A material that has a bandgap wavelength λg of about 1.7 μm, which is equal to or longer than that of a light receiving layer 106, is used for the well layer 104. For example, InGaAsP, InAsP, GaAsSb, AlInSb, AlGaSb, AlGaAsSb, AlGaAs, InAlAs and so forth are suitable as that material. An n⁺-InP contact layer 105 is formed 2 to 3 μm thick on the optical filter layer 102, and the light receiving layer 106 with a thickness of 2 to 3 μm is formed on the n contact layer 105.

A material that has a bandgap wavelength λg of about 1.65 μm, which is longer than 1.55 μm, is used for the light receiving layer 106. For example, InGaAsP, InAsP, GaAsSb, AlInSb, AlGaSb, AlGaAsSb, AlGaAs, InAlAs and so forth are suitable as that material. A p⁺-InP contact layer 107 is formed to a thickness of about 1.5 μm on the light receiving layer 106. The p contact layer 107 and the light receiving layer 106 are etched into a mesa shape to form a light receiving portion. An n electrode 108 is formed on the exposed n contact layer 105. A p electrode 109 is formed on the p contact layer 107. An antireflection film (AR coating film) 110 for 1.55 μm is formed on the light receiving surface (the bottom side of the semiconductor substrate 101).

The individual layers from the optical filter layer 102 to the p contact layer 107 are all formed by epitaxial growth, such as MO-CVD, MBE or VPE. The light receiving portion is formed by carrying out patterning by photolithography followed by wet etching or dry etching. The electrodes 108 and 109 are formed by performing a photolithography step, then depositing ohmic metal, lifting off unnecessary metal, sintering the ohmic metal to form an ohmic contact, then coating Ti/Pt/Au as interconnection and bonding metals. As ohmic metal, gold zinc (AuZn) is suitable on the p side, and gold germanium nickel (AuGeNi) is suitable on the n side. A nitride film (SiN film) provided by CVD is used for the AR coating film. The aforementioned process is used not only in the embodiment but also in other embodiments.

The operation of the first embodiment will be explained below. When light containing wavelengths of 1.3 μm and 1.55 μm is input to the back side of the device, the light passes the semiconductor substrate 101 in FIGS. 2A and 2B and enters the optical filter layer 102. The light of 1.3 μm is absorbed by the InGaAsP barrier layer 103 of the optical filter layer 102, thus generating carriers. The carriers move to the InGaAs well layer 104 and stay there for radiative recombination. The light of 1.3 μm is also absorbed by the InGaAs well layer 104 of the optical filter layer 102 for radiative recombination. While the InGaAs well layer 104 has the same composition as the InGaAs light receiving layer 106, deformation is given to the well layer 104 to make the bandgap wavelength slightly longer. The deformation is given by epitaxial growth with such element ratio as to increase the degree of lattice unmatching.

Therefore, the wavelength of secondary light generated by radiative recombination in the InGaAs well layer 104 becomes about the same length as the bandgap wavelength of the TnGaAs light receiving layer 106 or is not received by the InGaAs light receiving layer 106. While light of 1.55 μm is not absorbed by the InGaAsP barrier layer 103, it may be absorbed by the InGaAs well layer 104. If the total thickness of the InGaAs well layer 104 is so set as to make the absorption loss negligible, most light reaches the InGaAs light receiving layer 106 without being absorbed.

In other words, the use of the structure of the embodiment causes most of light of 1.3 μm and a small part of light of 1.55 μm to be absorbed by the optical filter layer but does not allow the secondary light generated by radiative recombination to be received by the light receiving layer 106, so that only the light of 1.55 μm can be selectively received by the light receiving layer 106.

(Second Embodiment)

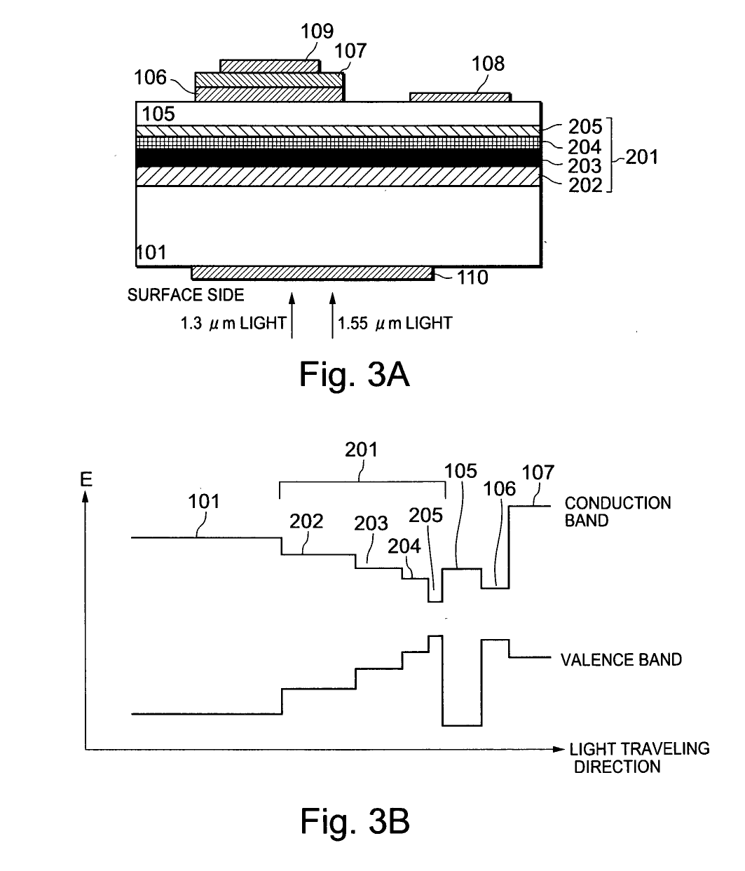

FIG. 3A presents a cross-sectional view of a light receiving device according to the second embodiment of the invention and FIG. 3B presents a band diagram of the light receiving device. An optical filter layer 201 is formed on a semiconductor substrate 101. A plurality of InGaAsP layers 202 to 204 (of materials whose bandgap wavelengths are shorter than that of the light receiving layer 6: λg202=about 1.35 μm, λg203=about 1.42 μm, λg204=about 1.50 μm) are laminated on the optical filter layer 201 in such a way that their bandgap wavelengths become gradually longer in the light traveling direction.

An InGaAs layer 205 (of the material whose bandgap wavelength is equal to or longer than that of the light receiving layer 106: λg205=about 1.35 μm) is formed on the topmost layer of the optical filter layer 201. The thicknesses of the layers 202 to 205 become smaller in the light traveling direction. An n⁺-InP contact layer 105 is formed on the optical filter layer 201, and the InGaAs light receiving layer 106 (of the material whose bandgap wavelength is longer than 1.55 μm: λg202=about 1.65 μm) is formed on n contact layer 105. A p⁺-InP contact layer 107 is formed on the light receiving layer 106.

The p contact layer 107 and the light receiving layer 106 are etched into a mesa shape to form a light receiving portion. An n electrode 108 is formed on'the exposed n contact layer 105. A p electrode 109 is formed on the p contact layer 107. An AR coating film 110 for 1.55 μm is formed on the light receiving surface (the bottom side of the semiconductor substrate 101).

When light containing wavelengths of 1.3 μm and 1.55 μm is input to the back side of the device of the embodiment in FIGS. 3A and 3B, the light passes the semiconductor substrate 101 and enters the optical filter layer 201. The light of 1.3 μm is absorbed first by the InGaAsP layer 202 of the optical filter layer 201, thus generating carriers. The carriers are recombined to generate secondary light. Because the secondary light has a wavelength about equal to the bandgap wavelength of the InGaAsP layer 202, it is absorbed by the InGaAsP layer 203 formed in the light traveling direction, thus generating carriers. The carriers are also radiated and recombined to generate third-order light.

The third-order light is absorbed by the overlying InGaAsP layer 204, thus generating carriers. The fourth-order light is absorbed by the topmost InGaAs layer 205, likewise generating fifth-order light, which is not however received by the light receiving layer 106. As the light that is generated by radiative recombination is emitted in all directions, the light emitted in the direction opposite to the light traveling direction becomes irrelevant to light reception in the device of the invention. That is, because only the light that is emitted in the light traveling direction is associated with light reception, the intensity of light generated by 1.3-μm light is reduced by repeating radiative recombination for the secondary light, the third-order light and the fourth-order light.

Meanwhile, although the light of 1.55 μm is hardly absorbed by the InGaAsP layer 202, the absorption ratio gradually increase in the light traveling direction. By making the InGaAsP layer 202 thicker and making the InGaAsP layer 203, the InGaAsP layer 204 and the InGaAs layer 205 gradually thinner, therefore, the loss of the light of 1.55 μm in the optical filter layer 202 can be suppressed. The optimization of the optical filter layer 201 this way improves the selectivity ratio of the light of 1.55.

(Third Embodiment)

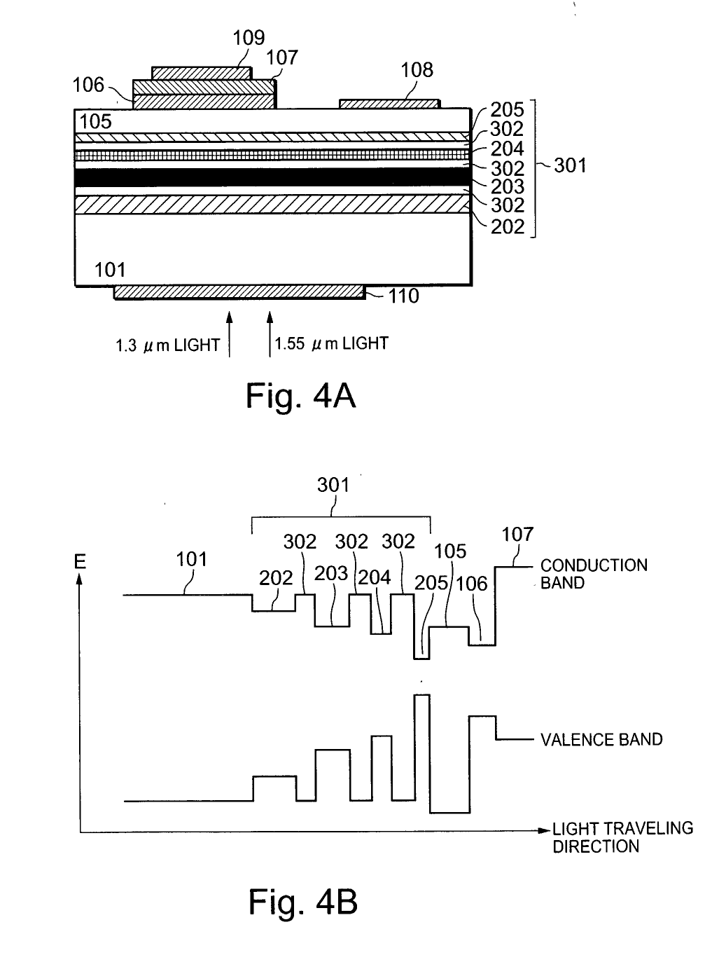

FIG. 4A presents a cross-sectional view of the third embodiment of the invention and FIG. 3B presents a band diagram thereof. An optical filter layer 301 is formed on a semiconductor substrate 101. A plurality of InGaAsP and InGaAs layers 202 to 205 similar to those of the second embodiment are laminated on the optical filter layer 301 in such a way that their bandgap wavelengths become gradually longer in the light traveling direction. Each of the InGaAsP and InGaAs layer 202 to 205 is sandwiched by barrier layers 302 of InP (the material whose bandgap wavelength is shorter than that of each layer: the material may be InGaAsP, InAlAs, InGaAlAs, InGaAs, InAsP or the like). An n⁺-InP contact layer 105 is formed on the optical filter layer 301, and an InGaAs light receiving layer 106 (of the material whose bandgap wavelength is longer than 1.55 μm) is formed on the n⁺-InP contact layer 105.

A p⁺-InP contact layer 107 is formed on the light receiving layer 106. The p⁺-InP contact layer 107 and the light receiving layer 106 are etched into a mesa shape to form a light receiving portion. An n electrode 108 is formed on the exposed n contact layer 105. A p electrode 109 is formed on the p contact layer 107. An AR coating film 110 for 1.55 μm is formed on the light receiving surface (the bottom side of the semiconductor substrate 101).

The device of the embodiment in FIGS. 4A and 4B has advantages similar to those of the second embodiment. In the second embodiment, if the individual layers of the optical filter layer 201 are set thin, the carriers generated in the layers 202 to 204 may be diffused in the layer 205 and radiative recombination may take place only in the layer 205. To reduce the influence of an optical signal of 1.3 μm, it is more effective to carry out radiative recombination a number of times than to carry out radiative recombination only in the layer 205. Therefore, the embodiment employs the MQW structure such that each of the layers 202 to 205 is sandwiched by the barrier layers 302 whose bandgap wavelength is shorter than that of the former each layer, so that radiative recombination is carried out forcibly, regardless of the thickness of each layer of the optical filter layer 201, to reduce the influence of an optical signal of 1.3 μm.

(Fourth Embodiment)

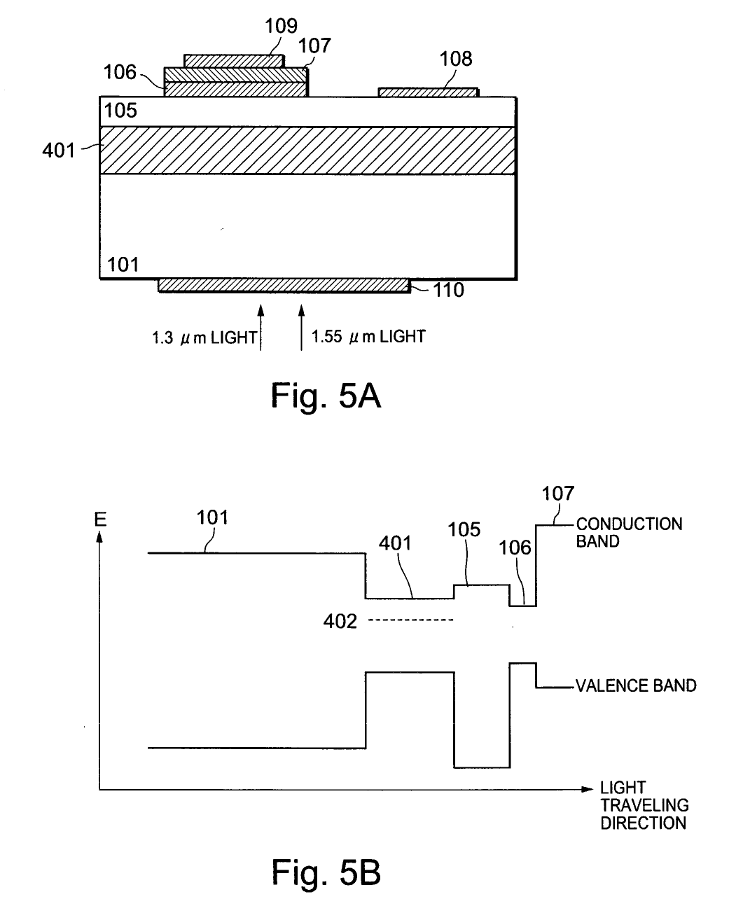

FIG. 5A presents a cross-sectional view of a light receiving device according to the fourth embodiment of the invention and FIG. 5B presents a band diagram thereof. An optical filter layer 401 is formed on a semiconductor substrate 101. An InGaAsP layer (of the material whose bandgap wavelength is about 1.4 μm, lying between 1.3 μm and 1.55 μm) is used as the optical filter layer 401, and is doped with an impurity to form an impurity level 402 in the band. An n⁺-InP contact layer 105 is formed on the optical filter layer 401, and an InGaAs light receiving layer 106 (of the material whose bandgap wavelength is longer than 1.55 μm) is formed on the n⁺-InP contact layer 105.

A p⁺-InP contact layer 107 is formed on the light receiving layer 106. The p⁺-InP contact layer 107 and the light receiving layer 106 are etched into a mesa shape to form a light receiving portion. An n electrode 108 is formed on the exposed n contact layer 105. A p electrode 109 is formed on the p contact layer 107. An AR coating film 110 for 1.55 μm is formed on the light receiving surface (the bottom side of the semiconductor substrate 101).

When light containing wavelengths of 1.3 μm and 1.55 μm is input to the back side of the device of the embodiment in FIGS. 5A and 5B, the light passes the semiconductor substrate 101 and enters the optical filter layer 401. The light of 1.3 μm is absorbed by the InGaAsP layer of the optical filter layer 401, thus generating carriers. The carriers fall to the impurity level 402. As the transition of electrons to the valence band from the impurity level 402 or the transition of electrons to the impurity level 402 from the conduction band, i.e., radiative recombination takes place, the light of 1.3 μm is not received by the light receiving layer 106 in case where the wavelength of emitted secondary light is nearly equal to or longer than the bandgap wavelength of the light receiving layer 106. Because the light of 1.55 μm is not absorbed by the optical filter layer 401, it is received as it is by the light receiving layer 106, thus improving the selectivity ratio of the light of 1.55.um.

Although the optical filter layer and the light receiving layer are formed in the named order with respect to the light input direction, short-wavelength side light is absorbed by the optical filter layer and the long-wavelength side light which has passed the optical filter layer is received by the light receiving layer in the first to fourth embodiments, the light receiving system (surface input type, back input type or side (edge) input type) may be varied as long as the same structure is employed.

(Fifth Embodiment)

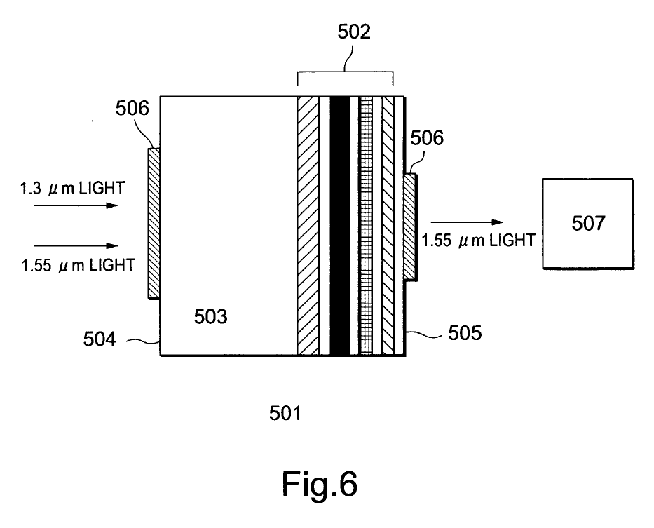

FIG. 6 is a schematic cross-sectional view of a case where the optical filter layer used in the first to fourth embodiments is separated from a photodiode (PD) device and is used as a bandpass filter 501. An optical filter layer 502 is formed on a semiconductor substrate 503 of InP, GaAs, Si or the like. An AR coating film 506 is formed on a light input surface 504 and a light transmitting surface 505. The optical filter layer 502 has only to take the structure of the any one of the optical filter layers used in the first to fourth embodiments. A photodiode (PD) device 507 as a light receiving device is provided at the back of the bandpass filter 501 with respect to the input light.

Because the optical filter layer 502 of any one of the first to fourth embodiments absorbs light and annihilates generated carriers without radiative recombination, a voltage need not be particularly applied to the optical filter layer 502, so that the optical filter layer 502 alone serves as a bandpass filter. The use of the embodiment can permit the use of a combination of existing PD devices.

(Sixth Embodiment)

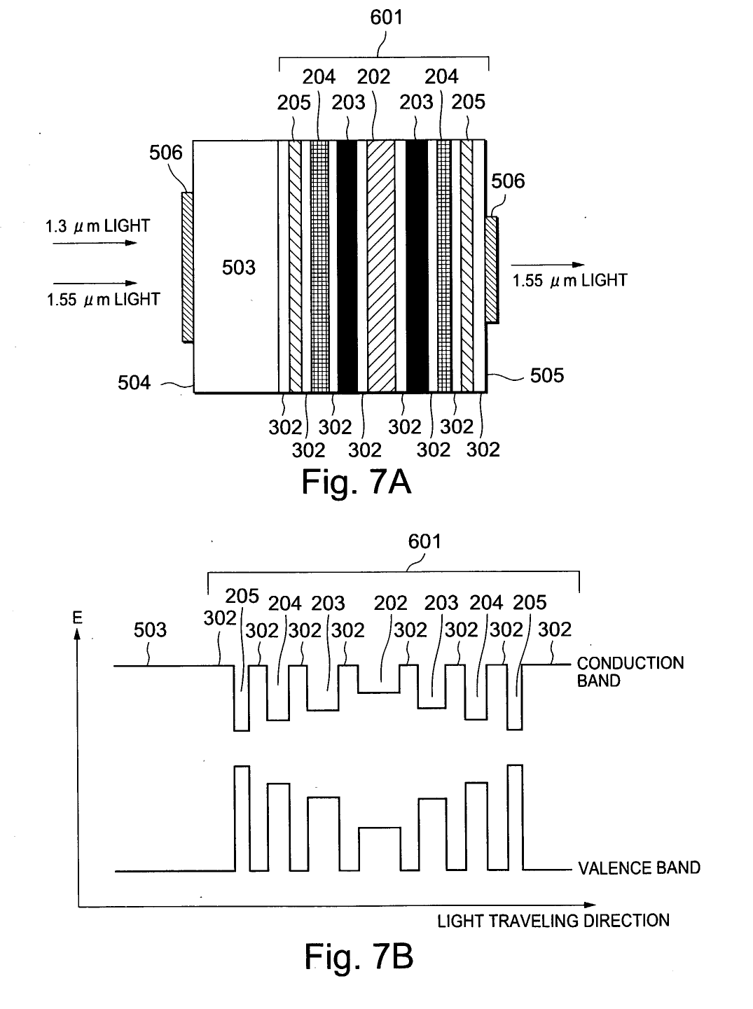

FIG. 7A presents a cross-sectional view of a semiconductor part having a bandpass filter capability according to the sixth embodiment of the invention and FIG. 7B is a band diagram of the semiconductor part. An optical filter layer is formed on a semiconductor substrate 503. The optical filter layer 601 comprises layers 202 to 205 and an InP barrier layer 302 as in the third embodiment. The individual layers are formed in the order of the !nP layer 302/InGaAs layer 205/InP layer 302/InGaAsP layer 204/InP layer 302/InGaAsP layer 203/InP layer 302/InGaAsP layer 202/InP layer 302/InGaAsP layer 203/InP layer 302/InGaAsP layer 204/InP layer 302/InGaAs layer 205/InP layer 302, with respect to the input direction of light. An AR coating film 506 is formed on a light input surface 504 and a light transmitting surface 505.

In the fifth embodiment, besides, long-wavelength side light which is selectively transmitted long-wavelength side light which is generated by radiative recombination and whose wavelength is not absorbed by the light receiving layer of the PD device is emitted from the light transmitting surface 505, while multiple lights whose wavelengths are about the same as the bandgap wavelength of each of the layers used for the optical filter layer are mixed and are emitted on that side of the light input surface 504. Because a layer structure similar to that in the light input direction is employed in the direction opposite to the light input direction in the embodiment, long-wavelength side light whose wavelength is not received by the PD device is emitted on both sides of the light input surface 504 and the light transmitting surface 505. This facilitates matching between the light input side and the light transmitting side, so that an optical device connected to the semiconductor part of this embodiment by an optical fiber is not influenced.

Although the foregoing description has been given of the preferable embodiments of the method of fabricating a semiconductor device according to the invention with reference to the accompanying drawings, the invention is not limited to those particular examples. It should be apparent to those skilled in the art that various modifications and alterations of the invention are possible within the spirit or scope of the invention as set forth in the appended claims, and may of course be included in the spirit or scope of the invention.

What is claimed is:

1. A semiconductor light receiving device which receives only long-wavelength side light in input light containing two wavelengths short-wavelength side light, and comprises:
a semiconductor substrate;
an optical filter layer formed on said semiconductor substrate;
a first conductivity type contact layer formed on said optical filter layer;
a light receiving layer having a bandgap wavelength longer than that of said long-wavelength side light and formed on said first conductivity type contact layer;
a second conductivity type contact layer formed on said light receiving layer;
a first conductivity type electrode formed on said first conductivity type contact layer;
a second conductivity type electrode formed on said second conductivity type contact layer; and
an antireflection film formed on a back surface of said semiconductor substrate,
whereby said optical filter layer annihilates carriers, generated in said optical filter layer by absorption of short-wavelength side light, by radiative recombination and decreases an intensity of short-wavelength side light produced by said radiative recombination.

2. The semiconductor light receiving device according to claim 1, wherein said optical filter layer has a multi-quantum well structure having a combination of a barrier layer having a bandgap wavelength which is an intermediate wavelength between wavelengths of said long-wavelength side light and said short-wavelength side light in said input light containing said two wavelengths and a well layer having a bandgap wavelength equal to or longer than that of said light receiving layer.

3. The semiconductor light receiving device according to claim 2, wherein a total thickness of said well layer is such that an absorption loss of said long-wavelength side light is negligible.

4. The semiconductor light receiving device according to claim 1, wherein said optical filter layer is a lamination of a plurality of layers having bandgap wavelengths longer than that of said short-wavelength side light in said input light containing said two wavelengths and shorter than that of said light receiving layer, and said bandgap wavelengths of said plurality of layers become longer and thickness of said plurality of layers become thinner in a light traveling direction.

5. The semiconductor light receiving device according to claim 1, wherein said optical filter layer is a lamination of a plurality of layers having bandgap wavelengths longer than that of said short-wavelength side light in said input light containing said two wavelengths and shorter than that of said light receiving layer, in pairs with said barrier layer having a bandgap wavelength shorter than said bandgap wavelengths of said plurality of layers, and said bandgap wavelengths of said plurality of layers become longer and thickness of said plurality of layers become thinner in a light traveling direction.

6. The semiconductor light receiving device according to claim 1, wherein said optical filter layer has a bandgap wavelength which is an intermediate wavelength between wavelengths of said long-wavelength side light and said short-wavelength side light in said input light containing said two wavelengths and contains an impurity to thereby form an impurity level.

7. A semiconductor part which receives only long-wavelength side light in input light containing two wavelengths short-wavelength side light, and comprises:
a semiconductor substrate;
an optical filter layer formed on said semiconductor substrate;
an antireflection film formed on said optical filter layer; and
an antireflection film formed on a back surface of said semiconductor substrate,
whereby said optical filter layer annihilates carriers, generated in said optical filter layer by absorption of short-wavelength side light, by radiative recombination and decreases an intensity of short-wavelength side light produced by said radiative recombination.

8. The semiconductor part according to claim 7, wherein said optical filter layer has a multi-quantum well structure having a combination of a barrier layer having a bandgap wavelength which is an intermediate wavelength between wavelengths of said long-wavelength side light and said short-wavelength side light in said input light containing said two wavelengths and a well layer having a bandgap wavelength equal to or longer than that of said light receiving layer.

9. The semiconductor part according to claim 7, wherein said optical filter layer is a lamination of a plurality of layers having bandgap wavelengths longer than that of said short-wavelength side light in said input light containing said two wavelengths and shorter than that of said light receiving layer, and said bandgap wavelengths of said plurality of layers become longer and thickness of said plurality of layers become thinner in a light traveling direction.

10. The semiconductor part according to claim 7, wherein said optical filter layer is a lamination of a plurality of layers having bandgap wavelengths longer than that of said short-wavelength side light in said input light containing said two wavelengths and shorter than that of said light receiving layer, in pairs with said barrier layer having a bandgap wavelength shorter than said bandgap wavelengths of said plurality of layers, and said bandgap wavelengths of said plurality of layers become longer and thickness of said plurality of layers become thinner in a light traveling direction.

11. The semiconductor part according to claim 7, wherein said optical filter layer has a bandgap wavelength which is an intermediate wavelength between wavelengths of said long-wavelength side light and said short-wavelength side light in said input light containing said two wavelengths and contains an impurity to thereby form an impurity level.

12. The semiconductor part according to claim 7, wherein said optical filter layer is a lamination of a plurality of layers having bandgap wavelengths longer than that of said short-wavelength side light in said input light containing said two wavelengths and shorter than that of said light receiving layer, in pairs with said barrier layer having a bandgap wavelength which is an intermediate wavelength between wavelengths of said long-wavelength side light and said short-wavelength side light in said input light containing said two wavelengths, and said bandgap wavelengths thickness of said plurality of layers temporarily become shorter and thicker respectively, and then become longer and thinner in a light traveling direction.
